(19) United States
(12) Patent Application Publication
(10) Pub. No.: US 2007/0290194 A1
(43) Pub. Date: Dec. 20, 2007

(54) Method for Cross-Linking an Organic Semi-Conductor

(76) Inventors: Heinrich Becker, Eppstein-Niederjosbach (DE); Klaus Meerholz, Rosrath (DE); David Muller, Munchen (DE)

Correspondence Address: CONNOLLY BOVE LODGE & HUTZ, LLP, P O BOX 2207, WILMINGTON, DE, 19899, US

(21) Appl. No.: 10/591,050

(22) PCT Filed: Feb. 25, 2005
(86) PCT No.: PCT/EP05/01978

§ 371 Date: May 14, 2007

(30) Foreign Application Priority Data
Feb. 26, 2004 (DE) 10 2004 009 355.5

(51) Int. Cl. H01L 51/30; H01L 51/40

(52) U.S. Cl. 257/40; 438/99; 257/E51.024

(57) ABSTRACT

The present invention describes a novel method for crosslinking organic semiconductors and conductors by initiating this crosslinking in an autophotosensitised manner. It furthermore describes the production of organic electronic devices through the use of this crosslinking method. The properties of the electronic devices are thereby improved.

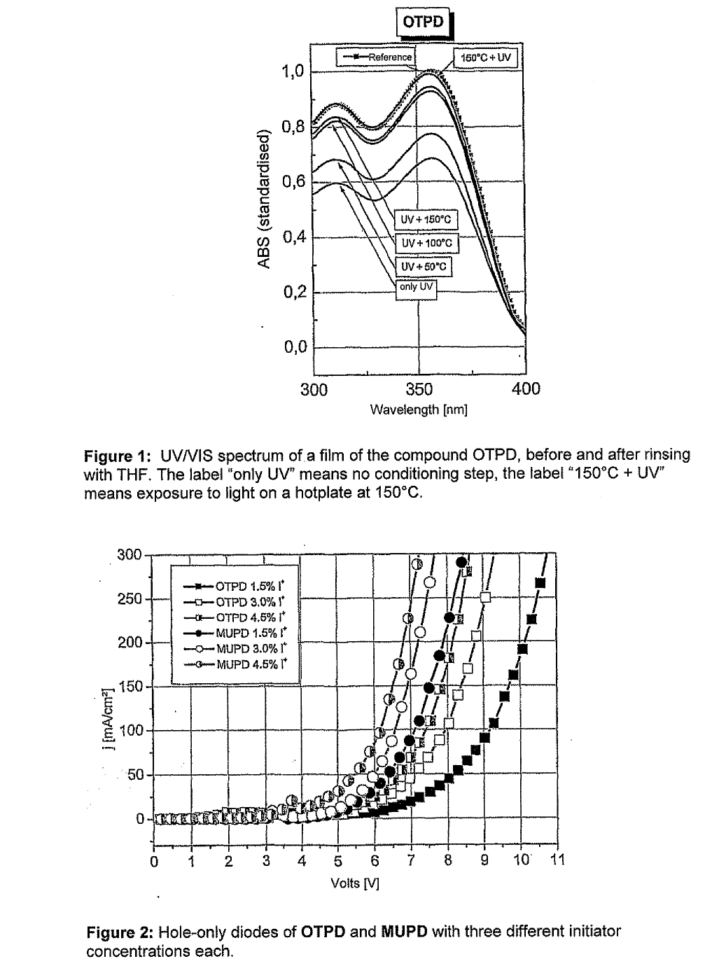

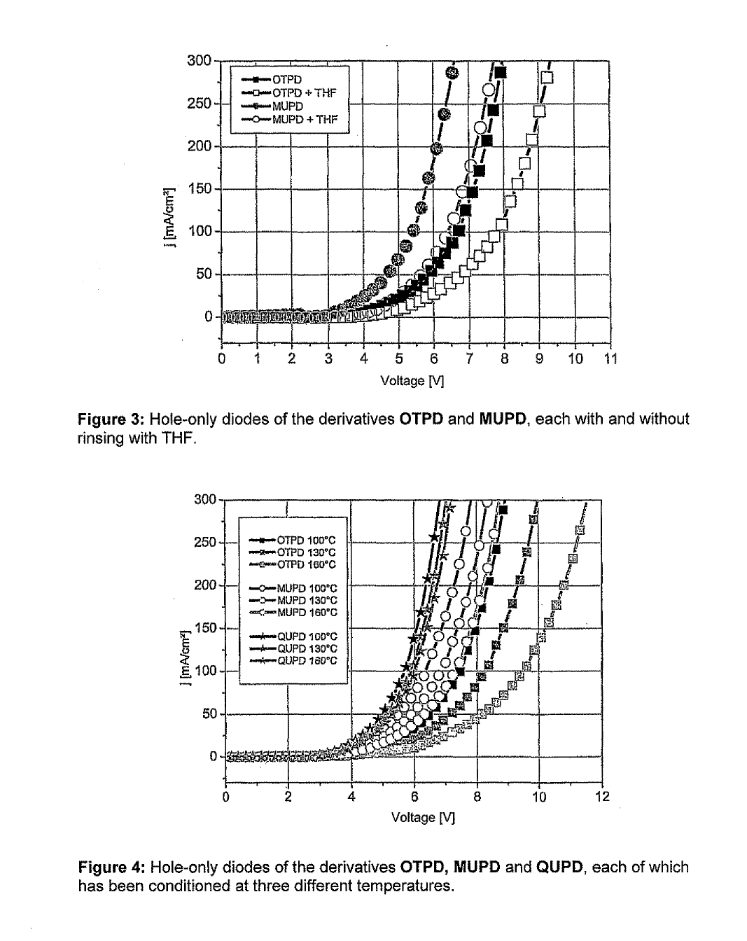

Organic electronic devices are being used ever more frequently in commercial products or are just about to be introduced onto the market. Examples which may be mentioned of products which are already commercial are organic or polymeric light-emitting diodes (OLEDs, PLEDs) in display devices. Organic solar cells (O-SCs), organic field-effect transistors (O-FETs), organic thin-film transistors (O-TFTs), organic integrated circuits (O-ICs), organic optical amplifiers or organic laser diodes (O-lasers) are well advanced at a research stage and could achieve major importance in the future.

An advantage of electronic devices based on polymeric or oligomeric organic semi-conductors is that they can be produced from solution, which is associated with less technical complexity and lower costs than vacuum processes, as are generally carried out for low-molecular-weight compounds. Thus, for example, single-coloured electroluminescent devices can be produced comparatively simply by processing the materials by surface coating from solution. The structuring, i.e. the addressing of the individual pixels, is usually carried out in the “supply lines” here, i.e. for example in the electrodes. This can be carried out, for example, through shadow masks in the manner of a stencil. For industrial mass production, however, significant disadvantages arise from this: the masks are unusable after single or multiple use due to deposit formation and have to be regenerated in a complex manner. For production, it would therefore be desirable to have available a process for which shadow masks are not required for deposition of the materials. In addition, surface coatings and structuring through shadow masks cannot be used if, for example, full-colour displays are to be produced from solution. For this purpose, the three primary colours (red, green, blue) must be applied alongside one another in individual pixels with high resolution. Whereas in the case of low-molecular-weight, vapour-depositable molecules, the pixels can be produced by the vapour deposition of the individual colours through shadow masks (with the associated difficulties already mentioned above), this is not possible for polymeric materials. A solution here consists in applying the active layer in a directly structured manner. That this causes considerable problems is understandable merely from the dimensions: structures in the region of a few 10 μm with layer thicknesses in the range from less than 100 nm to a few μm have to be created. Various printing techniques, such as, for example, ink-jet printing, have, in particular, recently been considered for this purpose. However, none of these printing techniques is in the meantime so mature that it would be usable for a mass-production process. The structurability by printing techniques must therefore currently still be regarded as an unsolved problem.

Another approach has been proposed in WO 02/10129 and Nature 2003, 421, 829, which describe structurable organic semiconductors and conductors which contain at least one crosslinking-capable oxetane group whose crosslinking reaction can be initiated and controlled in a targeted manner. For this purpose, at least one photo-initiator is admixed with the materials. Irradiation with UV light in the absorption band of the initiator produces an acid which initiates a crosslinking reaction through cationic, ring-opening polymerisation. Structured irradiation thus enables a pattern of areas with crosslinked and uncrosslinked material to be obtained. Rinsing with suitable solvents then enables the areas with uncrosslinked material to be removed, which results in the desired structuring. The crosslinked areas remain behind due to insolubility. Thus, a plurality of layers (or other materials in the vicinity of the first material) can be applied subsequently after crosslinking has been carried out. The irradiation as used for the structuring is a standard process of modern electronics (photolithography) and can be carried out, for example, using lasers or by flat irradiation through a corresponding photomask. This mask does not involve the risk of deposits since only radiation and not material flows through the mask.

However, the photoacid, or reaction products thereof, remains in the electronic device as impurity after the crosslinking. It is generally accepted that both organic and inorganic impurities can adversely affect the operation of electronic devices. It would therefore be desirable to be able to reduce the use of the photoacid as much as possible. In addition, the high-energy UV radiation necessary to date for the crosslinking can result in side reactions and decomposition of the organic semi-conductor and thus again adversely affect the operation of the electronic device. It would thus be desirable to have a milder crosslinking method available here.

The unpublished application DE 10340711.1 describes how a cationically cross-linkable interlayer between the emitting layer and a doped charge-injection layer in an OLED can be crosslinked by thermal treatment, presumably by means of protons from the doped charge-injection layer. This enables the addition of a photoacid to be avoided. However, this method can only be used if firstly a doped charge-injection layer is present and secondly crosslinking is to be carried out over a large area. Structuring is not possible in this way, and consequently this method cannot find broad application.

U.S. Pat. No. 6,593,388 describes how the rate of a cationic photopolymerisation can be accelerated by admixing a polymeric photosensitiser which absorbs in the range from 300 to 600 nm with a mixture of a cationically photopolymerisable monomer and an onium salt and irradiating the mixture. Low-molecular-weight photosensitisers are also described a number of times in the literature for this purpose (for example J. V. Crivello, Designed Monomers and Polymers 2002, 5, 141). The polymerisation thereby proceeds more quickly, and radiation of lower energy can be used. However, the disadvantage of an admixed photosensitiser, irrespective of whether it is of low molecular weight or polymeric, for organic electronic devices is clear: they are electronically active compounds which cannot be separated off completely from the film after crosslinking and which may thus, as impurity, adversely affect the functioning of the device, for example by affecting charge transport or by re-absorption and possibly re-emission of light. This approach is thus not suitable for the crosslinking of organic semiconductors.

Surprisingly, it has been found that the crosslinking proceeds more efficiently and quickly than in accordance with the prior art if the initiation of the crosslinking of oxetane-functionalised organic semiconductors is not carried out by irradiation in the absorption band of the photoacid. Less initiator (photoacid) is thus required, with the consequence that the device contains fewer impurities (in particular reaction products of the photoacid) after crosslinking and has better properties. Furthermore, it is not necessary, as in the case of crosslinking in accordance with the prior art, to irradiate with short-wave UV radiation in order to initiate the crosslinking reaction. This provides significant advantages since many organic compounds are not photostable, in particular to short-wave UV light. The milder crosslinking conditions enable undesired side reactions to be avoided. The electronic device consequently has better properties, in particular in relation to efficiency and lifetime, than devices whose crosslinking has been initiated in accordance with the prior art by shorter-wavelength (and thus higher-energy) UV irradiation.

The invention thus relates to a process for crosslinking oxetane-functionalised, organic semiconductors and conductors, preferably oligomeric and polymeric organic semiconductors and conductors, initiated by at least one added onium compound and by irradiation, characterised in that the irradiation is carried out outside the absorption band of the onium compound.

For the purposes of this invention, irradiation outside the absorption band of the onium compound is intended to mean that the absorbance of the onium compound at the irradiation wavelength is at most 5% of the maximum absorbance, preferably at most 3%, particularly preferably at most 1% of the maximum absorbance. It has been found that particularly good results are achieved if the irradiation is carried out at a wavelength at least 80 nm longer than the absorption maximum of the onium compound, preferably at least 100 nm longer. However, good results can also already be achieved if the separation between the irradiation wavelength and the absorption maximum of the onium compound is less than 80 nm.

For the purposes of this application, oxetane-functionalised means that at least one oxetane group is covalently bonded to at least one organic semiconductor or conductor, optionally via a spacer.

The invention furthermore relates to organic semiconducting layers, characterised in that they have been crosslinked by the process according to the invention.

The invention furthermore relates to a method for the production of organic electronic devices, characterised in that the process according to the invention for cross-linking an organic semiconductor or conductor is used for at least one layer.

The invention furthermore relates to organic electronic devices, characterised in that they comprise at least one layer crosslinked by the process according to the invention.

Layers of the crosslinked organic semiconductors and conductors known per se and electronic components which comprise such layers have already been described in the literature. The layers and electronic components produced by the process according to the invention exhibit improved morphological and electronic properties compared with those described to date (this is clearly confirmed, inter alia, in Example 3). In particular, the resistance of the layer to solvents and the efficiency and lifetime of the electronic device are considerably improved by the improved crosslinking conditions.

An onium compound is taken to mean a salt-like compound having a coordinatively saturated cation formed by the adduction of protons or other positive groups onto the central atom of a neutral molecule. These include, for example, ammonium compounds (R₄N⁺), oxonium compounds (R₃O⁺), sulfonium compounds (R₃S⁺), chloronium compounds (R₂Cl⁺), bromonium compounds (R₂Br³⁰ ), iodonium compounds (R₂I⁺), etc. It is known for some of these compounds that they act as photo-acid, i.e. liberate protons due to decomposition reactions on irradiation, generally in a wavelength range between 200 and 300 nm. Known and particularly suitable for this purpose are diaryliodonium, diarylbromonium, diarylchloronium, triarylsulfonium and dialkylphenacylsulfonium salts. Specific examples of photoacids are 4-(thio-phenoxyphenyl)diphenylsulfonium hexafluoroantimonate or {4-[(2-hydroxytetra-decyl)oxyl]phenyl}phenyliodonium hexafluoroantimonate and others as described in EP 1308781.

For the purposes of this text, organic semiconductors are compounds which, as a solid or as a layer, have semiconducting properties, i.e. in which the energy gap between conduction and valence band is between 0.1 and 4 eV. Suitable organic semiconductors or conductors are in principle low-molecular-weight, oligomeric, dendritic or polymeric semiconducting or conducting materials. For the purposes of this invention, an organic material is taken to mean not only purely organic materials, but also organometallic materials and metal coordination compounds with organic ligands. The materials here may be conjugated, non-conjugated or also partially conjugated, but preferably conjugated or partially conjugated, particularly preferably conjugated.

Preference is given to organic semiconductors and conductors in which at least one H atom has been replaced by a group of the formula (1), formula (2), formula (3) or formula (4) 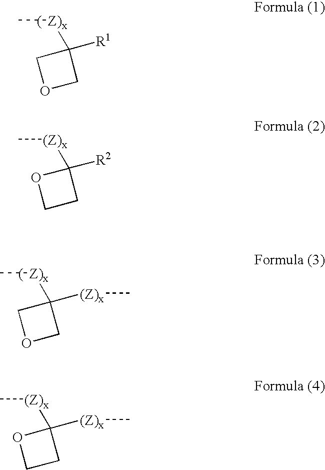
where the following applies to the symbols and indices used:
R¹ is on each occurrence, identically or differently, hydrogen, a straight-chain, branched or cyclic alkyl, alkoxyalkyl, alkoxy or thioalkoxy group having 1 to 20 C atoms, an aryl or heteroaryl group having 4 to 18 aromatic ring atoms or an alkenyl group having 2 to 10 C atoms, in which one or more hydrogen atoms may be replaced by halogen or CN and one or more non-adjacent C atoms may be replaced by —O—, —S—, —CO—, —COO—, —O—CO—,
R² is on each occurrence, identically or differently, hydrogen, a straight-chain, branched or cyclic alkyl or alkoxyalkyl group having 1 to 20 C atoms, an aryl or heteroaryl group having 4 to 18 aromatic ring atoms or an alkenyl group having 2 to 10 C atoms, in which one or more hydrogen atoms may be replaced by halogen or CN and one or more non-adjacent C atoms may be replaced by —O—, —S—, —CO—, —COO—, —O—CO—,
Z is on each occurrence, identically or differently, a divalent group —(CR³R⁴)ₙ—, in which, in addition, one or more non-adjacent C atoms may be replaced by —O—, —S—, —CO—, —COO— or —O—CO—,
   or a divalent aryl or N-, S- and/or O-heteroaryl group having 4 to 40 C atoms, which may also be substituted by one or more radicals R³,
R³, R⁴ are on each occurrence, identically or differently, hydrogen, a straight-chain, branched or cyclic alkyl, alkoxy, alkoxyalkyl or thioalkoxy group having 1 to 20 C atoms, an aryl or heteroaryl group having 4 to 20 aromatic ring atoms or an alkenyl group having 2 to 10 C atoms, in which one or more hydrogen atoms may also be replaced by halogen or CN; radicals R³ or R⁴ here may also form a ring system with one another or with R¹ or R²,
n is on each occurrence, identically or differently, an integer between 0 and 30, preferably between 1 and 20, in particular between 2 and 12,
x is on each occurrence, identically or differently, an integer between 0 and 5, preferably between 1 and 3,
   the proviso that the number of groups of the formula (1) or formula (2) is limited by the maximum number of available, i.e. substitutable, H atoms of the organic semiconductor or conductor.

The dashed bond in formulae (1) to (4) indicates the link to the organic semiconductor. It should not be taken to mean a methyl group here.

Compounds of the formula (3) and formula (4) are novel. They are therefore likewise a subject-matter of the present invention.

Particular preference is given to organic semiconductors and conductors in which at least one H atom has been replaced by a group of the formula (1).

One aspect of the invention relates to an organic conductor. This is preferably employed as charge-injection and/or charge-transport material. The organic conductor here may have both electron-conducting and hole-conducting properties.

A further aspect of the invention relates to an organic semiconductor. This is preferably employed as charge-injection material (for holes or for electrons) and/or as charge-transport material (for holes or for electrons) and/or as emission material, which can emit either from the singlet state or from the triplet state, and/or as blocking material, which can be, for example, a hole-, electron- and/or exciton-blocking material.

In a preferred aspect of the invention, the crosslinkable compound is a light-emitting compound. This can be crosslinked particularly efficiently by the crosslinking method according to the invention, giving a simple route to structured electronic devices having improved physical properties.

The crosslinkable layer may also be an oxetane-containing “buffer layer” introduced between a conductive, doped polymer and an organic semiconductor. The use of a buffer layer of this type is described in the unpublished application DE 10340711.1. Here too, the crosslinking method according to the invention offers a simple way of efficiently crosslinking the layer.

Preferred onium compounds are diaryliodonium, diarylbromonium, diarylchloronium and triarylsulfonium salts, particularly preferably diaryliodonium, diarylbromonium and diarylchloronium salts, where the anions are variable, but in general weakly nucleophilic anions, such as, for example, PF₆⁻, SbF₆⁻, SbCl₆⁻, BF₄⁻, B(C₆F₅)₄⁻, etc., are selected.

The proportion of the onium compound in the mixture or in the layer can be varied in broad ranges. However, it is preferred to keep the proportion as low as possible in order that the reaction products of the decomposition reaction influence the functioning of the electronic device as little as possible. On the other hand, it must be ensured that the proportion is sufficient to initiate the crosslinking as fully as possible. The proportion of the initiator (the onium compound) here can be optimised separately for each organic semiconductor and for each onium compound since different electronic properties of the semiconductor also influence its properties in the crosslinking. In general, it has proven preferable for the proportion of the onium compound in the mixture to be selected between 0.01 and 5% by weight, particularly preferably between 0.05 and 3% by weight, in particular between 0.1 and 2% by weight. These values apply in particular to diaryliodonium compounds and it is entirely possible for them to deviate therefrom for other compounds. It has been found as a rule of thumb here that a very low proportion of the onium compound, preferably in the range from 0.1 to 0.5% by weight, is adequate for good crosslinking in the case of semiconductors which are not readily oxidisable, while a higher proportion of the onium compound, preferably in the range from 1 to 2% by weight, is required for good crosslinking in the case of very electron-rich, readily oxidisable semiconductors.

It may also be preferred to post-treat the layer after the irradiation in order to complete the crosslinking and/or in order to remove reactive intermediates from the layer.

For this purpose, the layer can be conditioned, preferably in a temperature range from 50 to 250° C., in particular from 80 to 150° C., after irradiation is complete. The duration of the conditioning is preferably 0.1 to 10 minutes, in particular 1 to 3 minutes. Without wishing to be tied to a certain theory, we assume that this increases the mobility of the reactive oxetane units in the film and thus increases the degree of crosslinking. The temperature here is matched to the materials employed. Polymer networks are consequently obtainable which are de facto insoluble in THF and other common organic solvents.

The layer is furthermore preferably rinsed with a solvent, such as, for example, THF, after irradiation is complete and where appropriate after conditioning. Further additives may optionally be admixed with or dissolved in this solvent, for example reducing agents (for example LiAIH₄, MBDQ free-radical anions=2,6-dimethyl-2′,6′-di-tert-butyidiquinone free-radical anions, hydrazine, hydrazine derivatives, or the like) or weak bases/nucleophiles (for example tetrabutylammonium acetate or bromide, etc.). The concentration of these additives is low, preferably less than 10⁻⁴ mol/l, particularly preferably less than 10⁻⁵ mol/l. Surprisingly, it has been found that the layer consequently has better electronic properties. Without wishing to be tied to a certain theory, we assume that the reducing agents remove any free-radical cations formed (reduction to the neutral molecule), and the nucleophiles/bases neutralise cationic intermediates (for example oxonium ions) of the crosslinking reaction.

The crosslinking reaction, which proceeds in the presence of an onium compound and is initiated by irradiation, is characterised over the prior art in that the irradiation is not carried out in the absorption band of the onium compound. It is preferred here to irradiate at a wavelength at least 80 nm longer than the absorption maximum, particularly preferably at least 100 nm longer than the absorption maximum of the onium compound. These numerical values correspond to the separation of the crucial maxima of absorption and emission. This means that the onium compound cannot act directly as photoacid, i.e. cannot liberate a proton directly. Surprisingly, it has been found that the crosslinking of the oxetane groups nevertheless takes place very effectively and quickly and indeed the crosslinked layer is more resistant if the irradiation is carried out in the absorption band of the organic semiconductor or conductor instead of in the absorption band of the onium compound under otherwise identical conditions. Without wishing to be tied to a certain theory, we assume that the oxetane-functionalised conductor or semiconductor serves as photosensitiser for the reaction. The photosensitised cationic polymerisation of oxetanes is disclosed in principle in the literature, where the sensitisers used are also separately added polymers. However, it has hitherto not been described that a “macromonomer”, i.e. a polymer carrying crosslinkable groups, can also itself serve as photosensitiser. The sensitiser is consequently present in the film in proportions of virtually 100%. The fact that this type of “autosensitisation” actually works is a novel and surprising result. Compared with photosensitisation by separately added sensitisers, this is an enormous advantage for the production of electronic components since impurities, such as added sensitisers, must be substantially avoided there in order to produce the best-possible electronic properties.

The irradiation is preferably carried out in the absorption band of the organic semi-conductor, in particular at a wavelength in the region of up to +/−50 nm of the absorption maximum of the respective absorption band. For conjugated polymers based on poly-para-phenylene derivatives in the broadest sense (polyfluorenes, polyspirobifluorenes, etc.), the irradiation is preferably carried out, for example, in the range from 370 to 450 nm. The duration of the irradiation can be selected to be very short, with very good crosslinking results still being achieved. The irradiation is preferably carried out with a duration of 0.01 to 10 seconds, particularly preferably 0.1 to 3 seconds, where these times correspond to a light intensity of <1 mW/cm²; at higher intensities, even shorter exposure times may where appropriate be sufficient.

In one aspect of the invention, the crosslinkable compounds are charge-transport compounds, as already described above. The novel process offers an additional unexpected advantage here: if the film of the charge-transport compound cross-linked in accordance with the invention is not, as generally customary, treated after the crosslinking in order to complete the reaction and to remove charge carriers, this film has significantly better charge-transport properties than a film which has been conditioned and washed in the usual manner. Without wishing to be tied to a certain theory, we believe that the photoinduced reaction between the charge-transport compound and the added photoacid causes the formation of reactive species, for example free-radical cations, which are equivalent to (oxidative) doping of the polymer, on the charge-transport compound, resulting in a significant improvement in the charge-transport properties. The degree of doping can be adjusted via the precise conditions of the subsequent conditioning and/or rinsing steps with or without additives. However, if doping is undesired, this can also be removed again by a conditioning step and a rinsing step.

In a preferred embodiment, the process according to the invention is thus used for charge-transport materials in order to produce doping of the layer at the same time in addition to the crosslinking.

A comparable alternative method for simultaneous crosslinking and doping of charge-transport materials is direct oxidative initiation of the crosslinking reaction by addition of oxidants. This is likewise a subject-matter of the present invention. This also enables higher degrees of doping to be produced than is possible by photo-sensitisation. Suitable oxidants for this purpose are, for example, nitrosonium salts, but also salts of triarylammonium free-radical cations or other oxidants whose reaction products can easily be removed from the film after crosslinking, such as, for example, volatile or readily soluble compounds, or those whose reaction products are inert and do not have an adverse effect in the film on operation of the electronic device. Readily handled NO compounds here are, for example, NO(BF₄) or NO(SbF₆). Tris(4-bromophenylammonium) salts are examples of stable free-radical cations. The added oxidant enables firstly the crosslinking of the oxetane groups to be initiated, and secondly simultaneously facilitates oxidative doping of a charge-transport material. If the crosslinking is carried out by addition of oxidants and not by photoinduction, structuring is no longer possible, for which reason the method according to the invention mentioned above is preferred to the addition of oxidants, in particular for polymers which are to be structured.

It should furthermore be mentioned at this point that the presence of oxetane groups is not absolutely necessary for photosensitised doping of a charge-transport material by onium compounds, where the possibility of crosslinking is naturally excluded without the oxetane functionalisation. The invention thus furthermore also relates to the photosensitised doping of charge-transport materials by onium compounds, characterised in that irradiation is carried out outside the absorption band of the photoacid, preferably at a wavelength at least 80 nm longer, particularly preferably at least 100 nm longer, than the absorption maximum of the onium compound.

The devices are generally produced using a general process which is described in WO 02/10129 and in the unpublished application DE 10340711.1 and should be adapted in accordance with the novel crosslinking method, as described above.

The organic electronic device may consist of only one layer, which then comprises the oxetane-containing crosslinked compound, or may consist of a plurality of layers. It may be preferred here for more than one of these layers to be crosslinked. It may also be preferred for only one layer to be crosslinked and the other layers to be uncrosslinked. Further layers may be conductive, for example a doped, conducting charge-injection layer, such as, for example, polythiophene or polyaniline derivatives. They may also be semiconducting or non-conducting, such as, for example, the use of compounds having a high dielectric constant, for example LiF, NaF, BaF₂ etc., as electron-injection material.

For the purposes of this invention, electronic devices are organic and polymeric light-emitting diodes (OLEDs, PLEDs, for example EP-A-0 676 461, WO 98/27136), organic solar cells (O-SCs, for example WO 98/48433, WO 94/05045), organic field-effect transistors (O-FETs, for example U.S. Pat. No. 5,705,826, U.S. Pat. No. 5,596,208, WO 00/42668), organic thin-film transistors (O-TFTs), organic integrated circuits (O-ICs, for example WO 95/31833, WO 99/10939), organic optical amplifiers or organic laser diodes (O-lasers, for example WO 98/03566), but in particular organic and polymeric light-emitting diodes. For the purposes of this invention, organic means that at least one layer comprising at least one organic semiconductor or conductor is present.

Surprisingly, the novel crosslinking method now offers the following advantages over photoinduced crosslinking in accordance with the prior art, in which irradiation is carried out in the absorption band of the photoacid:
1) The crosslinking can be carried out under milder conditions than is possible in accordance with the prior art. While higher-energy UV radiation is necessary in the case of photoacids in order to liberate protons and thus to initiate the cross-linking, the reaction in the case of the process according to the invention can be initiated with light of significantly lower energy (=longer wavelength). In particular for organic semiconductors and conductors which are photochemically unstable (and this applies to most organic semiconductors and conductors in the case of the UV radiation required to date), the novel crosslinking method offers clear advantages since side reactions and decomposition in the layer by the high-energy UV radiation can be substantially avoided.
2) The crosslinking proceeds more quickly and effectively than is the case in accordance with the prior art. The crosslinking can thereby be carried out in a shorter time than is currently the case, which, due to the shorter exposure duration, in turn protects the material and reduces side reactions. In addition, the shorter crosslinking duration also represents a clear advantage in the industrial production process. The structuring of the device is consequently very efficient and likewise possible in a shorter time than hitherto.
3) The layers crosslinked by the method according to the invention with addition of less photoacid nevertheless have better resistance to solvents. They can consequently on the one hand be structured better, while on the other hand the application of a plurality of layers one on top of the other is also improved.
4) The physical properties of electronic devices crosslinked by the novel method, in particular the efficiency, the operating voltage and the lifetime, are better than the electronic devices in which the layers have been crosslinked by processes in accordance with the prior art. This is an unexpected and surprising effect. Without wishing to be tied to a certain theory, we assume that the reduced addition of photoacid could be responsible for this positive effect since fewer impurities (reaction products of the photoacid) consequently remain in the layer, and/or the use of milder crosslinking conditions and/or the shorter exposure duration.
5) After the photosensitised crosslinking of the layer, charges (free-radical cations) may remain on the organic semiconductor. This is advantageous, in particular, in the case of charge-transport and/or charge-injection materials since the additional charges then act as doping and thus increase the intrinsic conductivity of these materials, which is desirable for charge-transport properties. The degree of doping can be adjusted in accordance with the desired application by subsequent conditioning and/or rinsing steps.

The present invention is explained in greater detail by the following examples without wishing to be restricted thereto. These examples only discuss polymeric light-emitting diodes. However, the person skilled in the art will be able to produce further electronic devices, such as, for example, O-SCs, O-FETs, O-ICs, optical amplifiers and O-lasers, to mention but a few further applications, from the examples mentioned without inventive step.

### EXAMPLES

### Example 1

### General Procedure for Autophotosensitised Crosslinking

All process steps are carried out under inert gas. The appropriate amount of initiator (0.1-2% by weight) is added to the solutions of the semiconductor immediately before the spin coating. The initiator used in the following examples was {4-[(2-hydroxytetradecyl)oxyl]phenyl}phenyliodonium hexafluoroantimonate. The addition is carried out from freshly prepared stock solutions (10 mg/ml in THF). Immediately after the spin-coating process, the crosslinkable films are exposed over a large area or through a mask. The exposure sources used, besides standard UV hand lamps with conventional 4W tubes (UV-A, 365 nm), were principally GaN high-performance UV diodes (395 nm). Diodes of this type are commercially available in various designs from specialist electronic retailers. Exposure times of 1-3 s are sufficient, and the separation between substrate and exposure source is a few centimetres. In order to complete the crosslinking process, the films are conditioned at 90-150° C. for about 1 min. After the conditioning step or before application of the next layer, the films are rinsed with THF, for example on the spin coater by dribbling on an appropriate amount of solvent. A further conditioning step (“post-bake”), for example for 3 min. at 180-200° C., can optionally be carried out after the rinsing step.

### Example 2

### General Procedure for Oxidative Crosslinking

All process steps are carried out under inert gas. The appropriate amount of oxidant (for example 0.01-5% by weight) is added to the semiconductor solutions immediately before the spin coating. The oxidant used here was a solution of nitrosonium hexafluoroantimonate (NO⁺SbF₆⁻) in nitromethane. The addition is carried out from freshly prepared stock solutions (5 mg/ml in THF). After addition of the oxidant, the films are obtained by spin coating. Immediately thereafter, the films are conditioned at 100° C., which effects crosslinking of the films. It may be noted that a certain degree of crosslinking occurs even due to concentration of the solution during the spin-coating process, i.e. a certain resistance in the range 40-80% to solvents can be achieved even without a conditioning step. After the conditioning step or before application of the next layer, the films are rinsed with THF, for example on the spin coater by dribbling on an appropriate amount of solvent. At high doping concentrations, i.e. on addition of more than 1% by weight of NO⁺SbF₆⁻, an additional layer is usually applied in order to prevent a direct interaction between the highly doped layer and the subsequent electroluminescent polymer. A hole conductor having a higher oxidation potential, which is ideally between that of the doped (oxidatively crosslinked) layer and the EC polymer, is used for this purpose.

### Example 3

### Device Properties of PLEDs

Two-layer devices having an ITO//20 nm PEDOT//80 nm polymer//Ba//Ag structure were produced. The semiconductors used were red-, green- and blue-emitting conjugated polymers based on polyspirobifluorene which have been functionalised with oxetane groups. These materials and the synthesis thereof have already been described in the literature (Nature 2003, 421, 829). Various amounts of photoinitiator ({4-[(2-hydroxytetradecyl)oxyl]phenyl}phenyliodonium hexafluoroantimonate) were added thereto, and the layers were irradiated with light of various wavelengths and conditioned at various temperatures. Table 1 below shows the crosslinking conditions, in each case with the electroluminescence results.

TABLE 1
Device properties of polymers crosslinked by various methods

| Polymer^{a} | % of photoacid^{b} | λ/nm^{c} | t/s | Resistance^{d} | Efficiency/cd/A | U/V @ 100 cd/m² |
|---|---|---|---|---|---|---|
| P1 Comparison | none, not | — | — | 0% | 2.9 | 4.5 |
| | crosslinked | | | | | |
| P1 Comparison | 0.5 | 302 | 3 | 100% | 3.0 | 4.5 |
| P1 Comparison | 0.4 | 302 | 1 | 90% | 3.1 | 4.5 |
| P1 | 0.4 | 395 | 1 | 100% | 3.2 | 4.4 |
| P2 Comparison | none, not | — | — | 0% | 7.0 | 3.8 |
| | crosslinked | | | | | |
| P2 Comparison | 0.5 | 302 | 3 | 100% | 6.5 | 3.8 |
| P2 Comparison | 0.4 | 203 | 1 | 90% | 6.7 | 3.8 |
| P2 | 0.4 | 395 | 1 | 100% | 6.9 | 3.7 |
| P3 Comparison | none, not | — | — | 0% | 1.0 | 8.3 |
| | crosslinked | | | | | |
| P3 Comparison | 0.5 | 302 | 3 | 100% | 1.1 | 7.5 |
| P3 Comparison | 0.4 | 302 | 1 | 90% | 1.2 | 7.5 |
| P3 | 0.4 | 395 | 1 | 100% | 1.3 | 7.3 |

^{a}Crosslinkable polymers in accordance with Nature 2003, 421, 829-833
^{b}% by weight, based on the weight of the polymer
^{c}Irradiation wavelength
^{d}Resistance to THF, determined by the absorption in % after rinsing with THF (reference: unrinsed substrate)

As can clearly be seen, the crosslinking using the method according to the invention takes place in a shorter time and nevertheless more completely, evident from the use of less initiator with the same resistance to solvents than is the case in accordance with the prior art. If, by contrast, irradiation in the absorption band of the photoacid is only carried out for a shorter time under otherwise identical conditions, the solvent resistance of the polymer film drops.

Furthermore, it is clearly evident from the device examples that the properties in the device improve if the films have been crosslinked by the method according to the invention.

1. Process for crosslinking oxetane-functionalised, organic semiconductors and conductors which comprises initiating by irradiation in the presence of at least one added onium compound wherein the irradiation is carried out outside the absorption band of the onium compound.

2. Process according to claim 1, wherein the irradiation is carried out at a wavelength at least 100 nm longer than the absorption maximum of the onium compound.

3. Process according to claim 1, wherein the organic semiconductor or conductor is oligomeric or polymeric.

4. Process according to claim 1, wherein at least one H atom in the organic semiconductor or conductor has been replaced by a group of the formula (1), formula (2), formula (3) or formula (4) 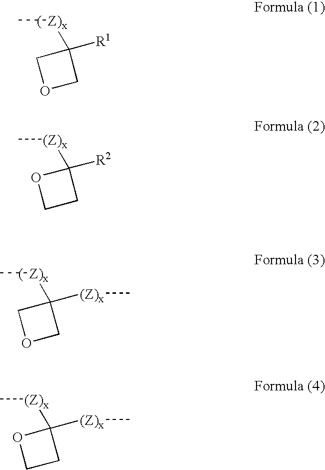
where the following applies to the symbols and indices used:
R¹ is on each occurrence, identically or differently, hydrogen, a straight-chain, branched or cyclic alkyl, alkoxyalkyl, alkoxy or thioalkoxy group having 1 to 20 C atoms, an aryl or heteroaryl group having 4 to 18 aromatic ring atoms or an alkenyl group having 2 to 10 C atoms, in which one or more hydrogen atoms is optionally replaced by a halogen or CN and one or more non-adjacent C atoms is optionally replaced by —O—, —S—, —CO—, —COO—, —O—CO—,
R² is on each occurrence, identically or differently, hydrogen, a straight-chain, branched or cyclic alkyl or alkoxyalkyl group having 1 to 20 C atoms, an aryl or heteroaryl group having 4 to 18 aromatic ring atoms or an alkenyl group having 2 to 10 C atoms, in which one or more hydrogen atoms is optionally replaced by a halogen or CN and one or more non-adjacent C atoms is optionally replaced by —O—, —S—, —CO—, —COO—, —O—CO—,
Z is on each occurrence, identically or differently, a divalent group —(CR³R⁴)ₙ₋, in which, in addition, one or more non-adjacent C atoms is optionally replaced by —O—, —S—, —CO—, —COO— or —O—CO—,
or a divalent aryl and/or N-, S- and/or O-heteroaryl group having 4 to 40 C atoms, which is optionally substituted by one or more radicals R³,
R³ and R⁴ are on each occurrence, identically or differently, hydrogen, a straight-chain, branched or cyclic alkyl, alkoxy, alkoxyalkyl or thioalkoxy group having 1 to 20 C atoms, an aryl or heteroaryl group having 4 to 20 aromatic ring atoms or an alkenyl group having 2 to 10 C atoms, in which one or more hydrogen atoms is optionally replaced by a halogen or CN; radicals R³ or R⁴ here optionally form a ring system with one another or with R¹ or R²,
n is on each occurrence, identically or differently, an integer between 0 and 30,
x is on each occurrence, identically or differently, an integer between 0 and 5,
wherein the number of the groups of the formula (1) or formula (2) is limited by the maximum number of available H atoms of the organic semiconductor or conductor; the dashed bond indicates the link to the organic semiconductor.

5. Process according to claim 4, wherein at least one H atom in the organic semiconductor or conductor has been replaced by a group of the formula (1).

6. Process according to claim 1, wherein the organic semiconductor has charge-transport properties, emission properties, blocking properties or a combination of charge-transport properties, emission properties and blocking properties.

7. Process according to claim 1, wherein the onium compound employed comprises at least one diaryliodonium, diarylbromonium, diarylchloronium or triarylsulfonium salt.

8. Process according to claim 1, wherein the proportion of the onium compound in the mixture is between 0.01 and 5% by weight.

9. Process according to claim 8, wherein the proportion of the onium compound in the mixture is between 0.1 and 2% by weight.

10. (canceled)

11. (canceled)

12. (canceled)

13. (canceled)

14. (canceled)

15. Process according to claim 14, wherein at least one reducing agent and/or at least one weak base or nucleophile is added to the solvent.

16. Process according to claim 1, wherein the irradiation is carried out at a wavelength in the region of up to +/−50 nm of the absorption maximum of the absorption band of the organic semiconductor.

17. Process according to claim 1, wherein the duration of the irradiation is between 0.01 and 10 seconds at a light intensity of <1 mW/cm².

18. Process according to claim 1, wherein in addition to the crosslinking, doping of the layer occurs at the same time by incompletely conditioning and/or rinsing the layer after the irradiation.

19. Compounds of the formula (3) and formula (4) 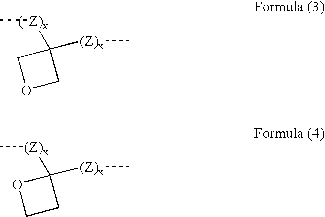
where the following applies to the symbols and indices used:
R¹ is on each occurrence, identically or differently hydrogen, a straight-chain, branched or cyclic alkyl, alkoxyalkyl, alkoxy or thioalkoxy group having 1 to 20 C atoms, an aryl or heteroaryl group having 4 to 18 aromatic ring atoms or an alkenyl group having 2 to 10 C atoms, in which one or more hydrogen atoms is optionally replaced by a halogen or CN and one or more non-adjacent C atoms is optionally replaced by —O—, —S—, —CO—, —COO—, —O—CO—,
R² is on each occurrence, identically or differently, hydrogen, a straight-chain, branched or cyclic alkyl or alkoxyalkyl group having 1 to 20 C atoms, an aryl or heteroaryl group having 4 to 18 aromatic ring atoms or an alkenyl group having 2 to 10 C atoms, in which one or more hydrogen atoms is optionally replaced by a halogen or CN and one or more non-adjacent C atoms is optionally replaced by —O—, —S—, —CO—, —COO—, —O—CO—,
Z is on each occurrence, identically or differently, a divalent group —(CR³R⁴)ₙ—, in which, in addition, one or more non-adjacent C atoms is optionally replaced by —O—, —S—, —CO—, —COO— or —O—CO—,
or a divalent aryl and/or N-, S- and/or O-heteroaryl group having 4 to 40 C atoms, which is optionally substituted by one or more radicals R³,
R³ and R⁴ are on each occurrence, identically or differently, hydrogen, a straight-chain, branched or cyclic alkyl, alkoxy, alkoxyalkyl or thioalkoxy group having 1 to 20 C atoms, an aryl or heteroaryl group having 4 to 20 aromatic ring atoms or an alkenyl group having 2 to 10 C atoms, in which one or more hydrogen atoms is optionally replaced by a halogen or CN; radicals R³ or R⁴ here optionally form a ring system with one another or with R¹ or R²,
n is on each occurrence, identically or differently, an integer between 0 and 30,
x is on each occurrence, identically or differently, an integer between 0 and 5,
wherein the number of the groups of the formula (1) or formula (2) is limited by the maximum number of available H atoms of the organic semiconductor or conductor; the dashed bond indicates the link to the organic semiconductor.

20. Process for crosslinking and optionally simultaneous doping of oxetane-containing organic semiconductors, which comprises adding at least one oxidant to a crosslinking reaction.

21. Process for the photosensitised doping of organic semiconductors or conductors by photoacids, which comprises carrying out irradiation outside the absorption band of the photoacid.

22. Organic semiconducting layers which have been produced by the process according to claim 1.

23. (canceled)

24. Organic electronic device, comprising at least one layer produced by the process according to claim 1.

25. Organic electronic device according to claim 24, wherein the device is an organic or polymeric light-emitting diode (OLED, PLED), organic solar cell (O-SC), organic field-effect transistor (O-FET), organic thin-film transistor (O-TFT), organic integrated circuit (O-IC), organic optical amplifier or organic laser diode (O-laser).

26. Process according to claim 20 wherein doping of the oxetane-containing organic semiconductors occurs simultaneously with the crosslinking of said semiconductors.

27. A process to produce a semiconductor layer which comprises crosslinking a layer according to the process of claim 1.

28. Process according to claim 27, wherein the layer is post-treated after the irradiation.

29. Process according to claim 27, wherein the layer is conditioned after the irradiation.

30. Process according to claim 27, wherein the layer is conditioned in a temperature range from between 50 and 250° C.

31. Process according to claim 29, wherein the layer is conditioned for between 0.1 and 10 minutes.

32. Process according to claim 27 wherein the layer is rinsed with a solvent after irradiation.

33. Process according to claim 32, wherein at least one reducing agent and/or at least one weak base or nucleophile is added to the solvent.
